(19) United States
(12) Patent Application Publication
(10) Pub. No.: US 2014/0224644 A1
(43) Pub. Date: Aug. 14, 2014

(54) DEPOSITION APPARATUS AND METHOD OF MANUFACTURING ORGANIC LIGHT EMITTING DISPLAY APPARATUS USING THE SAME

(71) Applicant: SAMSUNG DISPLAY CO., LTD., Yongin-City (KR)

(72) Inventor: Su-Hyuk Choi, Yongin-City (KR)

(73) Assignee: SAMSUNG DISPLAY CO., LTD., Yongin-City (KR)

(21) Appl. No.: 14/010,383

(22) Filed: Aug. 26, 2013

(30) Foreign Application Priority Data
Feb. 12, 2013 (KR) 10-2013-0014976

(51) Int. Cl. H01J 37/32

(52) U.S. Cl. CPC H01J 37/3244
USPC 204/192.15; 204/298.07

(57) ABSTRACT

A deposition apparatus includes a chamber, a chamber, a substrate placing unit which is located in the chamber and on which a substrate is placed, and a sputter unit for forming a thin film on the substrate. The sputter unit includes a first target unit and a second target unit facing the first target unit. A pair of targets are mounted on each of the first target unit and the second target unit. Argon gas is directly injected between the pair of targets. Accordingly, plasma may be more effectively and stably formed. A method of manufacturing an organic light-emitting display apparatus using the deposition apparatus is also disclosed.

### CROSS-REFERENCE TO RELATED PATENT APPLICATION

This application claims priority to and the benefit of Korean Patent Application No. 10-2013-0014976, filed on Feb. 12, 2013, in the Korean Intellectual Property Office, the content of which is incorporated herein in its entirety by reference.

### BACKGROUND

1. Field

One or more aspects of the present invention relate to a deposition apparatus and a method of manufacturing an organic light-emitting display apparatus using the same.

2. Description of the Related Art

An organic light-emitting display apparatus is a self-emitting display apparatus that includes a hole-injecting electrode, an electron-injecting electrode, and an organic light-emitting diode (OLED) formed therebetween and including an organic emission layer. In the organic light-emitting display apparatus, light is generated when an exiton generated when holes injected via the hole-injecting electrode and electrons injected via the electron-injecting electrode are combined at the organic emission layer is changed to a ground state from an exited state.

The organic light-emitting display apparatus which is a self-emitting display apparatus does not need an additional light source, can thus be driven at a low voltage and manufactured to be light and thin, and has high performances, such as a wide viewing angle, high contrast, and a fast response rate. Thus, the organic light-emitting display apparatus has drawn attention as a next-generation display apparatus. However, since the performance of the organic light-emitting display apparatus is likely to be degraded due to external moisture or oxygen, the OLED should thus be sealed to be protected against external moisture, oxygen, or the like.

Recently, in order to manufacture a thin film and/or flexible organic light-emitting display apparatus, a thin film encapsulating layer has been used to seal the OLED. Sputtering may be used as a method of forming such a thin film encapsulating layer.

Sputtering is a representative method used in a film-forming process during manufacture of a thin film transistor (TFT) liquid crystal display (LCD), a flat panel display apparatus such as organic electroluminescent display apparatus, or various electronic devices, and is known as a dry process technique of a wide application range. However, when sputtering is used, temperature of a target increases due to a continuous collision between the target and particles assuming electric charges, thereby preventing a film from being continuously formed. Also, since an inert gas such as argon gas is introduced from the outside of a chamber, a small amount of the argon gas may thus permeate into the thin film, thereby degrading the performance of the thin film formed.

### SUMMARY

Aspects of embodiments of the present invention are directed toward a deposition apparatus having improved deposition efficiency and a method of manufacturing an organic light-emitting display apparatus using the same. And aspects of embodiments of the present invention are directed toward a deposition apparatus including a sputter unit with a pair of targets facing each other and a method of manufacturing an organic light-emitting display apparatus using the same.

According to an embodiment of the present invention, there is provided a deposition apparatus including a chamber, a substrate placing unit which is located in the chamber and on which a substrate is to be placed, and a sputter unit for forming a thin film on the substrate. The sputter unit includes a first target unit and a second target unit facing the first target unit. The first and second target units are configured to be mounted by a pair of targets, respectively. The first and second target units are configured to allow argon gas to be directly injected between the pair of targets.

The sputter unit may further include a first side portion and a second side portion facing each other and contacting corners of the first and second target units, and a lower surface portion extending in a direction crossing (i.e., perpendicular to) the first target unit, the second target unit, the first side portion, and the second side portion. The argon gas may be injected via an inlet hole formed in at least one among the first side portion, the second side portion, and the lower surface portion.

The first target unit may include a first cooling water flow path for cooling the target mounted on the first target unit. The second target unit may include a second cooling water flow path for cooling the target mounted on the second target unit. The first cooling water flow path and the second cooling water flow path may be separated from each other to independently circulate cooling water.

A third cooling water flow path may be formed in the first side portion, a fourth cooling water flow path may be formed in the second side portion, and a fifth cooling water flow path may be formed in the lower surface portion.

The third to fifth cooling water flow paths may be connected to one another, and the third to fifth cooling water flow paths are configured to circulate cooling water independently from the first and second cooling water flow paths.

One of the third to fifth cooling water flow paths may be connected to one of the first and second cooling water flow paths, and the other two cooling water flow paths among the third to fifth cooling water flow paths may be connected to the other cooling water flow path among the first and second cooling water flow paths.

Each of the first and second target units may further include magnetic field generators disposed at rear sides of the target thereof. The magnetic field generators of the first target unit and the magnetic field generators of the second target unit may be disposed such that magnetic poles thereof are opposite to each other.

The sputter unit may be located outside of the chamber.

The pair of targets may include a low-liquidus temperature material.

The low-liquidus temperature material may include at least one selected from the group consisting of tin fluorophosphate glass, chalcogenide glass, tellurite glass, borate glass, and phosphate glass.

According to another embodiment of the present invention, there is provided a deposition apparatus including a chamber, a substrate placing unit which is located in the chamber and on which a substrate is placed, and a sputter unit for forming a thin film on the substrate. The sputter unit may have a rectangular parallelepiped shape, the upper end of which is open, and may include a first target unit and a second target unit facing the first target unit. The first and second target units are configured to be mounted by a pair of targets, respectively. The first and second target units are configured to allow argon gas to be directly injected between the pair of targets.

The low-liquidus temperature material may include at least one selected from the group consisting of tin fluorophosphate glass, chalcogenide glass, tellurite glass, borate glass, and phosphate glass.

The sputter unit may further include a first side portion and a second side portion facing each other, and contacting corners of the first and second target units; and a lower surface portion extending along a direction crossing (i.e., perpendicular to) the first target unit, the second target unit, the first side portion, and the second side portion. The argon gas may be injected via an inlet hole formed in at least one among the first side portion, the second side portion, and the lower surface portion.

The first target unit may include a first cooling water flow path for cooling the target mounted thereon. The second target unit may include a second cooling water flow path for cooling the target mounted thereon. The first cooling water flow path and the second cooling water flow path may be separated from each other to independently circulate cooling water.

A third cooling water flow path may be formed in the first side portion, a fourth cooling water flow path may be formed in the second side portion, and a fifth cooling water flow path may be formed in the lower surface portion.

The third to fifth cooling water flow paths may be connected to one another, and the third to fifth cooling water flow paths are configured to circulate cooling water independently from the first and second cooling water flow paths.

One of the third to fifth cooling water flow paths may be connected to one of the first and second cooling water flow paths, and the other two cooling water flow paths among the third to fifth cooling water flow paths may be connected to the other cooling water flow path among the first and second cooling water flow paths.

The sputter unit may be located outside the chamber.

According to another embodiment of the present invention, there is provided a method of manufacturing an organic light-emitting display apparatus, the method including forming a display unit on a substrate, placing the substrate in a chamber; and forming an encapsulating film to seal the display unit. The forming of the encapsulating film may be performed by sputtering using a pair of targets facing each other. The pair of targets may include a low-liquidus temperature material. During the sputtering, argon gas may be directly injected between the pair of targets.

The sputtering may be performed by a sputter unit including a first target unit and a second target unit on which the pair of targets are respectively mounted to face each other; a first side portion and a second side portion facing each other and contacting corners of the first and second target units; and a lower surface portion extending along a direction crossing (i.e., perpendicular to) the first target unit, the second target unit, the first side portion, and the second side portion. The argon gas may be directly injected between the pair of targets via an inlet hole formed in at least one among the first side portion, the second side portion, and the lower surface portion.

During the sputtering, the pair of targets may be independently cooled.

The pair of targets may be located outside the chamber.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross sectional view of a deposition apparatus according to an embodiment of the present invention;

FIG. 2 is a schematic perspective view of a sputter unit included in the deposition apparatus of FIG. 1;

FIG. 3 is a schematic cross sectional view of the sputter unit of FIG. 2;

FIGS. 4(A) and 4(B) each illustrate states of a target when the target is cooled;

FIG. 5 is a schematic cross sectional view of a modified example of the deposition apparatus of FIG. 1;

FIG. 6 is a schematic cross sectional view of an organic light-emitting display apparatus according to an embodiment of the present invention; and

FIG. 7 is an enlarged view of a part of a display unit included in the organic light-emitting display apparatus of FIG. 6.

### DETAILED DESCRIPTION

Hereinafter, aspects of the present invention will be described more fully with reference to the accompanying drawings, in which exemplary embodiments of the invention are shown. This invention may, however, be embodied in many different forms and should not be construed as limited to the exemplary embodiments set forth herein. It would be obvious to those of ordinary skill in the art that the exemplary embodiments are to cover all modifications, equivalents, and alternatives falling within the scope of the invention. In the following description, well-known functions or constructions are not described in detail if it is determined that they would obscure the invention due to unnecessary detail.

It will be understood that, although the terms ‘first’, ‘second’, ‘third’, etc., may be used herein to describe various elements, components, regions, layers and/or sections, these elements, components, regions, layers and/or sections should not be limited by these terms. These terms are only used to distinguish one element, component, region, layer or section from another region, layer or section.

It will be understood that when an element or layer is referred to as being “on” an other element or layer, the element or layer can be directly on the other element or layer, or intervening element(s) or layer(s) may be interposed therebetween. In contrast, when an element is referred to as being “directly on” another element or layer, there are no intervening elements or layers present.

In the drawings, elements that are substantially the same or that correspond to each other are assigned the same reference numeral and are not redundantly described. Also, the lengths and sizes of layers and regions may be exaggerated for clarity.

As used herein, the term ‘and/or’ includes any and all combinations of one or more of the associated listed items. Expressions such as “at least one of,” when preceding a list of elements, modify the entire list of elements and do not modify the individual elements of the list.

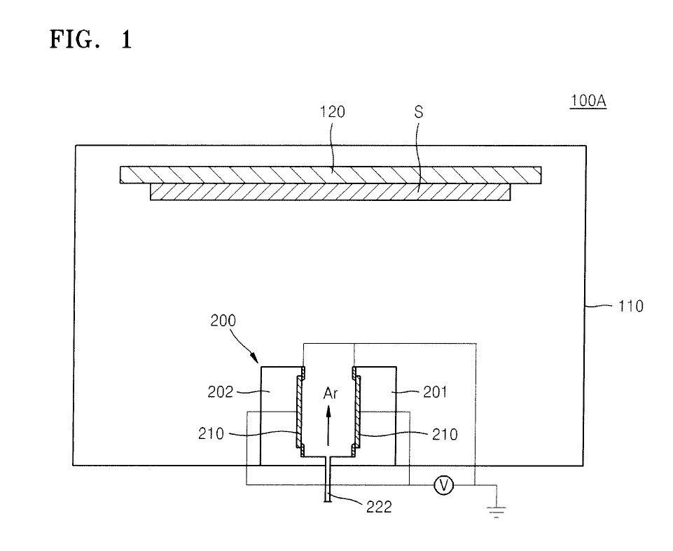

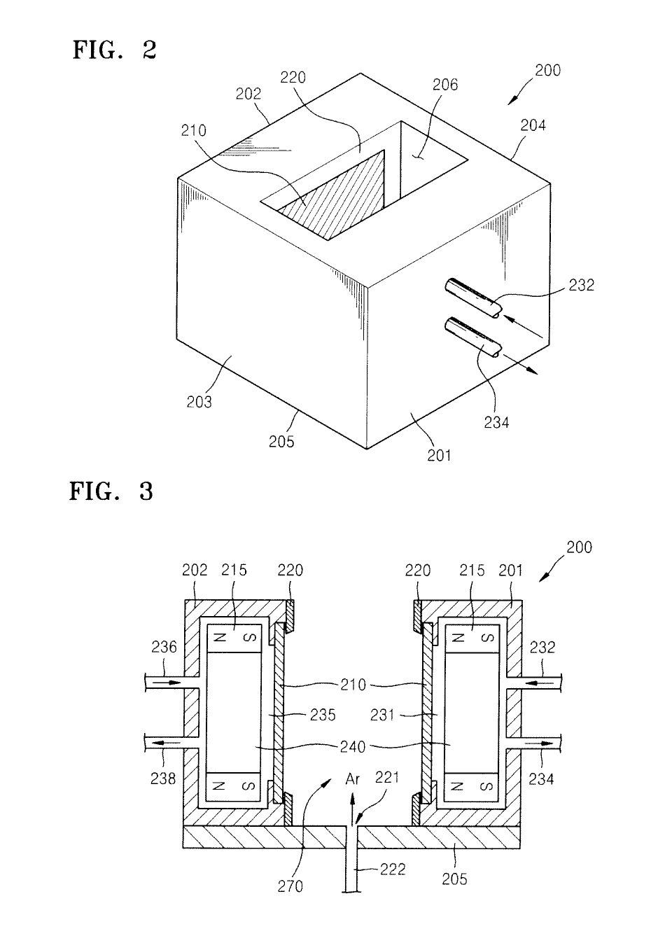

FIG. 1 is a schematic cross sectional view of a deposition apparatus 100A according to an embodiment of the present invention. FIG. 2 is a schematic perspective view of a sputter unit 200 included in the deposition apparatus 100A of FIG. 1. FIG. 3 is a schematic cross sectional view of the sputter unit 200 of FIG. 2.

First, referring to FIG. 1, the deposition apparatus 100A may include a chamber 110, a substrate placing unit 120 that is placed in the chamber 110 and on which a substrate S is placed, and the sputter unit 200 configured to form a thin film on the substrate S.

The chamber 110 may accommodate elements, such as the sputter unit 200, the substrate placing unit 120, etc., therein, and may be connected to a vacuum pump so that the inside thereof may be maintained at a vacuum state.

The substrate placing unit 120 may transfer the substrate S into the chamber 110 while the substrate S is placed thereon, and may support the substrate S such that the substrate S faces the sputter unit 200.

The sputter unit 200 forms a thin film on the substrate S by sputtering. The sputter unit 200 may include a first target unit 201 and a second target unit 202 that faces the first target unit 201. A pair of targets 210 are respectively mounted on the first target unit 201 and the second target unit 202 to face each other. Argon (Ar) gas is directly injected between the pair of targets 210.

The pair of targets 210, the first target unit 201, and the second target unit 202 are electrically connected to a power supply unit, e.g., a direct current (DC) power source, via a power supply line. However, the power supply unit is not limited to the DC power source, and may be a radio-frequency (RF) power source using direct-current offset voltage formation or DC pulse power.

When power is supplied among the pair of targets 210, the first target unit 201, and the second target unit 202, a discharge occurs in a space 270 of FIG. 3 between the pair of targets 210 facing each other, and the argon gas is thus ionized to form plasma.

According to an embodiment of the present invention, since the argon gas is directly injected between the pair of targets 210, plasma may be stably formed to prevent the argon gas from colliding against and permeating into a thin film formed on the substrate S, thereby suppressing the properties of the thin film from being influenced by the argon gas.

The sputter unit 200 will now be described with reference to FIGS. 2 and 3 in more detail.

Referring to FIGS. 2 and 3, the sputter unit 200 may have a rectangular parallelepiped shape, the upper end of which is open. More specifically, the sputter unit 200 may include a first target unit 201 and a second target unit 202 facing the first target unit 201, a first side portion 203 and a second side portion 204 facing the first side portion 203 and contacting corners of the first and second target units 201 and 202, and a lower surface portion 205 extending in a direction crossing (e.g., perpendicular to) the first target unit 201, the second target unit 202, the first side portion 203, and the second side portion 204. Also, an opening 206 may be formed in the upper end of the sputter unit 200.

Each of the first target unit 201 and the second target unit 202 may include one of the pair of targets 210, a shielding unit 220 functioning as an anode, and magnetic field generators 215 that generate a magnetic field. Also, since the first target unit 201 includes a first cooling water flow path 231 and the second target unit 202 includes a second cooling water flow path 235, the pair of targets 210 may be independently cooled.

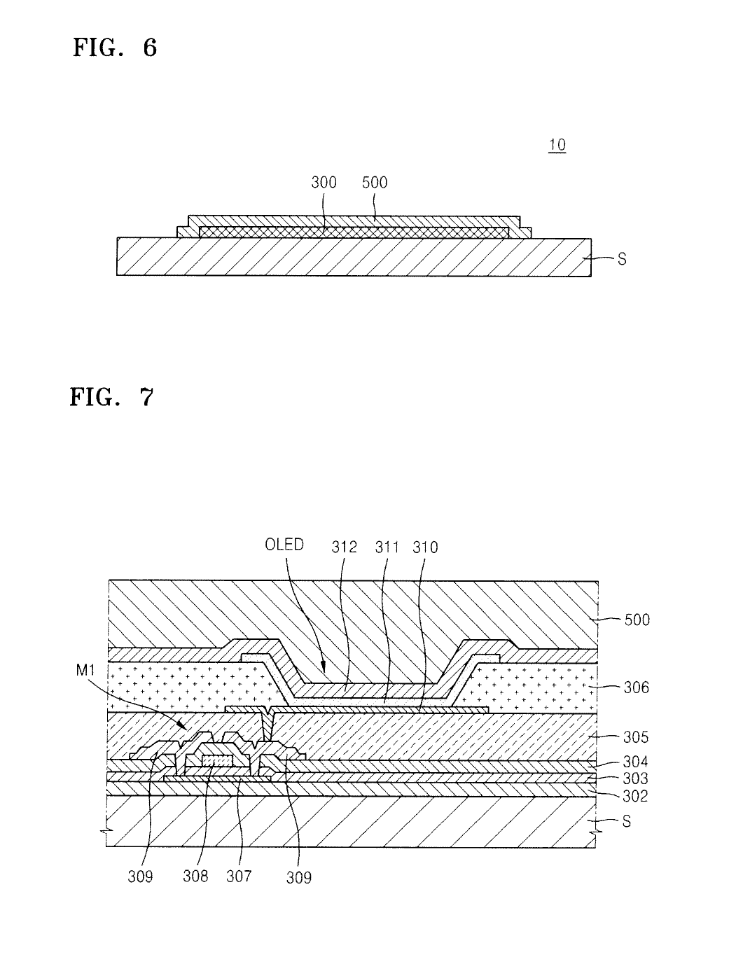

The pair of targets 210 are formed of a material to be formed on the substrate S. According to an embodiment of the present invention, the target 210 may include a low-liquidus temperature material. More specifically, the target 210 may include at least one selected from the group consisting of tin fluorophosphate glass, chalcogenide glass, tellurite glass, borate glass, and phosphate glass. A thin film formed using the target 210 is used to form an encapsulating layer 500 of FIG. 6 included in an organic light-emitting display apparatus 10 of FIG. 6 which will be described below.

The shielding unit 220 is disposed at front edges of the target 210, and is grounded to function as an anode. The shielding unit 220 is spaced slightly from the target 210, and may be processed such that a surface thereof is not sputtered.

The magnetic field generators 215 may be disposed on rear sides of the target 210. More specifically, the magnetic field generators 215 may be formed of a ferromagnetic body, such as a ferrite or neodium-based magnet (e.g., neodium, iron, boron, etc) or a samarium cobalt-based magnet, and may be disposed along an external wall of the target 210. Also, the magnetic field generators 215 may be located on a rear surface of the target 210, and may be fixed by being inserted into a main block body 240 formed of an insulator.

The magnetic field generators 215 of the first target unit 201 and the magnetic field generators 215 of the second target unit 202 are disposed such that magnetic poles thereof are opposite to each other. Thus, a magnetic field connecting the pair of targets 210 is formed, and a plasma region may be restricted to the space 270 between the pair of targets 210.

Although not shown, a yoke plate may be located on each of the rear surfaces of the pair of targets 210. The yoke plate allows a magnetic field formed by the magnetic field generators 215 to be evenly distributed in the space 270 between the pair of targets 210. The yoke plate may be formed of a material that may have magnetic properties due to the magnetic field generators 215, e.g., a ferromagnetic body including any one of iron, cobalt, nickel, and an alloy thereof.

In operation, sputtering may be performed by supplying power to the pair of targets 210 functioning as cathodes and injecting, for example, argon gas which is an inert gas to the pair of targets 210. More specifically, when a negative voltage is applied to the pair of targets 210, a discharge occurs in the space 270 between the pair of targets 210 facing each other, and electrons generated by the discharge collide against the argon gas to generate argon ions, thereby generating plasma. In this case, the argon gas passes through an inlet pipe 222 connected to an external tank (not shown) and is then directly injected into the space 270 between the pair of targets 210 via an inlet hole 221.

According to the current embodiment, the inlet hole 221 is formed in the lower surface portion 205, but the present invention is not limited thereto. Although not shown, the inlet hole 221 may be formed in the first side portion 203 and/or the second side portion 204, instead of the lower surface portion 205. Also, the inlet hole 221 may be formed in not only the lower surface portion 205 but also the first side portion 203 and/or the second side portion 204. That is, the inlet hole 221 may be formed in at least one among the first side portion 203, the second side portion 204, and the lower surface portion 205.

As described above, if argon gas is directly injected into the space 270 between the pair of targets 210 during sputtering, plasma may be more effectively and stably formed and may prevent the argon gas from permeating into a thin film formed on the substrate S so as not to increase internal stress in the thin film. Also, the characteristics of the thin film, such as a growth structure, may be prevented from being influenced by the argon gas by suppressing a collision between the argon gas and the thin film on the substrate S.

The plasma generated during sputtering is confined in the space 270 between the pair of targets 210 due to a magnetic field generated by the magnetic field generators 215, and particles assuming electric charges, such as electrons, negative ions, and positive ions, make a reciprocal movement between the pair of targets 210 along a magnetic force line and are thus confined in the plasma in the space 270 between the pair of targets 210. Also, particles having high energy among the particles sputtered by one of the pair of targets 210 are also accelerated toward the other target 210, and a thin film may thus be formed on the substrate S due to diffusion of neutral particles having relatively low energy without influencing the substrate S perpendicular to the surfaces of the pair of targets 210. Thus, the substrate S may be prevented from being damaged due to a collision between the substrate S and the particles having high energy.

However, temperatures of the pair of targets 210 increase due to a continuous collision between the pair of targets 210 and the ions in the plasma. In general, a reactive gas, such as nitrogen, oxygen, and hydrocarbon, may remain on the pair of targets 210. When the temperatures of the pair of targets 210 increase while the reactive gas remains thereon, an additional chemical reaction may occur to form a chemical compound on the surfaces of the pair of targets 210. The chemical compound may reduce the speed of sputtering and cause arcing to occur. To counter this issue, the pair of targets 210 should be cooled during sputtering.

To this end, in the sputter unit 200 according to an embodiment of the present invention, the first target unit 201 includes the first cooling water flow path 231, and the second target unit 202 includes the second cooling water flow path 235, so as to cool the pair of targets 210. The first cooling water flow path 231 and the second cooling water flow path 235 are separated to independently circulate cooling water, thereby independently cooling the pair of targets 210.

For example, the first cooling water flow path 231 is connected to a first inlet pipe 232 via which cooling water flows in and a first outlet pipe 234 via which the cooling water is discharged, and the second cooling water flow path 235 may be connected to a second inlet pipe 236 and a second outlet pipe 238 and separated from the first cooling water flow path 231. When additional cooling water is supplied to the first cooling water flow path 231 and the second cooling water flow path 235, the temperatures of the pair of targets 210 heated may be effectively lowered.

Also, a third cooling water flow path may be formed in the first side portion 203, a fourth cooling water flow path may be formed in the second side portion 204, and a fifth cooling water flow path may be formed in the lower surface portion 205. In this case, the third to fifth cooling water flow paths may be connected to one another, in which cooling water may circulate independently from the first cooling water flow path 231 and the second cooling water flow path 235. That is, three cooling circulation lines may be formed in the sputter unit 200 to effectively cool the pair of targets 210.

One of the third to fifth cooling water flow paths may be connected to one of the first cooling water flow path 231 and the second cooling water flow path 235, and the other two cooling water flow paths may be connected to the other cooling water flow path 231 or 235, thereby forming two independent cooling circulation lines in the sputter unit 200.

For example, cooling water flowing into the first cooling water flow path 231 forms one cooling circulation line via the third cooling water flow path formed in the first side portion 203, and cooling water flowing into the second cooling water flow path 232 form another cooling circulation line via fourth cooling water flow path formed in the second side portion 204 and the fifth cooling water flow path formed in the lower surface portion 205. In this case, the first outlet pipe 234 connected to the first cooling water flow path 231 may be formed to be connected to the third cooling water flow path, and the second outlet pipe 238 connected to the second cooling water flow path 235 may be formed to be connected to the fifth cooling water flow path.

However, the present invention is not limited thereto, and the sputter unit 200 may be configured to have any of various other suitable cooling circulation lines. However, the first cooling water flow path 231 and the second cooling water flow path 235 configured to cool the pair of targets 210, respectively, should be separated from each other, and inflowing cooling water should be circulated while flowing into the first cooling water flow path 231 and the second cooling water flow path 235 so as to effectively cool the pair of targets 210.

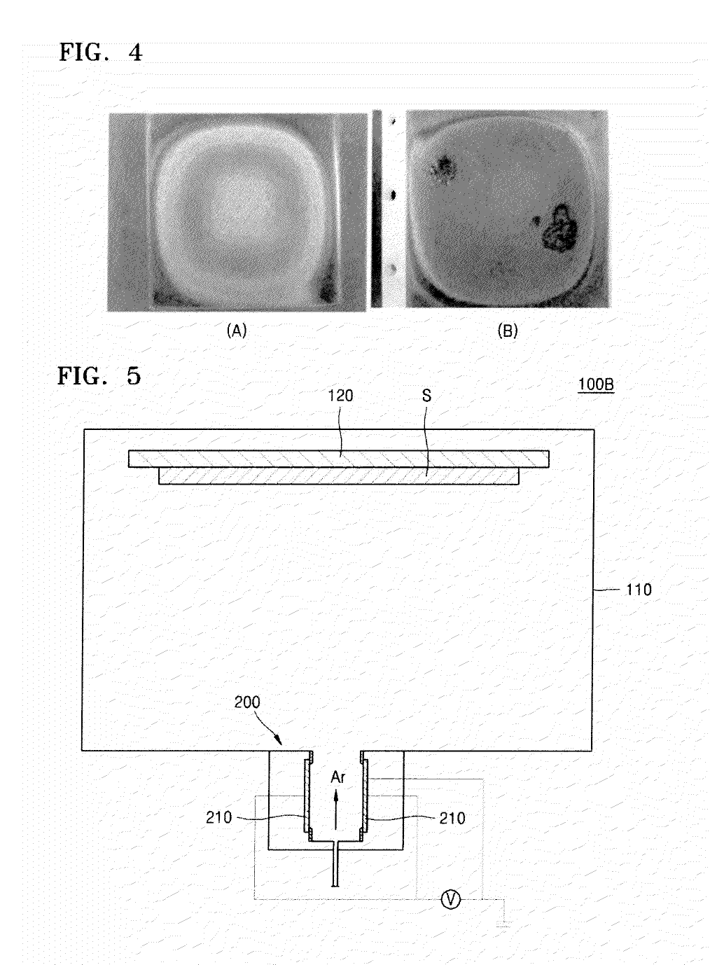

Table 1 below shows a case in which three cooling circulation lines are formed in the sputter unit 200 (example 1), a case in which one cooling circulation line is formed in the sputter unit 200 (comparative example 1), and states of the pair of targets 210 in each of the cases. FIGS. 4(A) and 4(B) illustrate states of the pair of targets 210 according to Table 1. Here, comparative example 1 illustrates a cooling circulation line, in which cooling water flows into first cooling water flow path 231, sequentially passes through the third to fifth cooling water flow paths, and is then discharged via the second cooling water flow path 235. Specifically, FIG. 4(A) illustrates the states of the pair of targets 210 according to example 1 of the present invention, and FIG. 4(B) illustrates the states of the pair of targets 210 according to comparative example 1. Here, the pair of targets 210 used were formed of tin fluorophosphate glass containing 20 to 80 weight % of tin (Sn), 2 to 20 weight % of phosphate (P), 3 to 20 weight % of oxygen (O), and 10 to 36 weight % of fluorine (F).

TABLE 1

| | Cooling water | | Number of | |
|---|---|---|---|---|
| | supply | | cooling | State of |
| | temperature | Power | circulation lines | target |
| Example 1 | 18° C. | 2 KW DC | Three | Good |
| | | Pulse | | |
| Comparative | 18° C. | 2 KW DC | One | Bad |
| example 1 | | Pulse | | |

As illustrated in Table 1 and FIGS. 4(A) and 4(B), in the case of comparative example 1 in which the pair of targets 210 were not independently cooled, a chemical compound was formed on surfaces of the pair of targets 210 as a discharge voltage and the temperatures of the pair of targets 210 increased during sputtering. In such a state, arcing occurred when a thin film was continuously formed. In contrast, in the case of example 1, as the pair of targets 210 were independently cooled, cooling efficiency was improved, the states of the pair of targets 210 were favorable and sputtering was continued without causing arching to occur. Thus, a thin film may thus be continuously formed, thereby improving deposition efficiency. Example 1 shows that the discharge voltage was lowered by about 30% and was stably maintained, compared to comparative example 1.

FIG. 5 is a schematic cross sectional view of a deposition apparatus 100B which is a modified example of the deposition apparatus 100A of FIG. 1.

Referring to FIG. 5, the deposition apparatus 100B may include a chamber 110, a substrate placing unit 120 that is placed in the chamber 110 and on which a substrate S is placed, and a sputter unit 200 configured to form a thin film on the substrate S. The chamber 110, the substrate placing unit 120, and the sputter unit 200 are as illustrated in and described above with reference to FIGS. 1 to 3, and are thus not described again here.

In the deposition apparatus 100B of FIG. 5, the sputter unit 200 is located outside the chamber 110. For example, an opening formed in an upper end of the sputter unit 200 may be connected to an opening formed in a lower end of the chamber 110. When the sputter unit 200 is located outside the chamber 110 as described above, the sputter unit 200 may be easily attached to and detached from the chamber 110 and a work time needed to replace the pair of targets 210 with other targets may thus be saved.

FIG. 6 is a schematic cross sectional view of an organic light-emitting display apparatus 10 according to an embodiment of the present invention. FIG. 7 is an enlarged view of a part of a display unit 300 included in the organic light-emitting display apparatus 10 of FIG. 6.

Referring to FIGS. 6 and 7, the organic light-emitting display apparatus 10 may include a substrate S, a display unit 300 formed on the substrate S, and an encapsulating layer 500 for sealing the display unit 300.

The substrate S may be formed of a glass material, or may be formed of a plastic material, such as acryl, polyimide, polycarbonate, polyester, or Mylar, to add flexible properties to the organic light-emitting display apparatus 10. Also, an insulating layer 302, such as a barrier layer and/or a buffer layer, may be formed on an upper surface of the substrate S to prevent diffusion of impurity ions into the substrate S, protect the substrate S against moisture or external air, and planarize a surface of the substrate S.

The display unit 300 may include a driving thin-film transistor (TFT) M1 and an organic light-emitting diode OLED formed on the substrate S as illustrated in FIG. 7. Although FIG. 7 illustrates a top emission type display as an example of the display unit 300, the present invention is not limited thereto and the display unit 300 may be a bottom emission type display or may have any of other various suitable structures different from that illustrated in FIG. 7.

An active layer 307 of the driving TFT M1 may be formed of a semiconductor material, and a gate insulating film 303 may be disposed to cover the active layer 307. The active layer 307 may be formed of an inorganic semiconductor material, such as amorphous silicon or polysilicon, or an organic semiconductor material.

A gate electrode 308 is formed on the gate insulating film 303, and an interlayer insulating film 304 is formed to cover the gate electrode 308. Source-drain electrodes 309 are formed on an interlayer insulating film 304, and a passivation film 305 and a pixel defining film 306 are sequentially formed to cover the source-drain electrodes 309.

The gate electrode 308 and the source-drain electrodes 309 may be formed of a metal, such as Al, Mo, Au, Ag, Pt/Pd, or Cu, but are not limited thereto. The gate electrode 308 and the source-drain electrodes 309 may be formed by applying a resin paste of these metals in powder form or may each be a conductive polymer.

Each of the gate insulating film 303, the interlayer insulating film 304, the passivation film 305, and the pixel defining film 306 may be embodied as an insulator, may have a single-layer structure or a multi-layer structure, and may be formed of an organic material, an inorganic material, or a combination (e.g., a compound) thereof.

Although not shown, a switching TFT and a storage capacitor may be formed according to the process of forming the driving TFT M1. However, the driving TFT M1 is not limited to a stacked structure illustrated in FIG. 7, and may be any of other various TFTs.

The organic light-emitting diode OLED emits red, green, or blue light according to flow of current to display information regarding an image, and may include a pixel electrode 310 connected to one of the source and drain electrodes 309 of the driving TFT M1, an opposite electrode 312 formed to cover all of pixels, and an organic emission film 311 disposed between the pixel electrode 310 and the opposite electrode 312 to emit light.

The encapsulating layer 500 is formed to entirely cover the display unit 300 so as to protect the display unit 300 against external moisture and oxygen.

The encapsulating layer 300 may be formed of a glass material, and may thus be effectively protected against external moisture and oxygen. Specifically, the encapsulating layer 300 may be formed of a low-liquidus temperature material. For example, the encapsulating layer 300 may include at least one selected from the group consisting of tin fluorophosphate glass, chalcogenide glass, tellurite glass, borate glass, and phosphate glass.

A method of manufacturing an organic light-emitting display apparatus 10 according to an embodiment of the present invention will now be briefly described with reference to FIGS. 5 to 7.

The organic light-emitting display apparatus 10 may be manufactured by forming the display unit 300 on the substrate S, placing the substrate S in the chamber 110, and forming the encapsulating film 500 to seal the display unit 300.

The display unit 300 may have a structure as described above but may be any of well-known various organic light-emitting displays. Thus, a method of manufacturing the display unit 300 is not described again here.

The encapsulating layer 500 may be formed by sputtering using the sputter unit 200 including the pair of targets 210 facing each other. The pair of targets 210 each contains a low-liquidus temperature material, and argon gas which is an inert gas may be directly injected between the pair of targets 210 during sputtering. Furthermore, since the pair of targets 210 may be independently cooled during sputtering, sputtering may be stably performed without causing arching to occur.

Since the encapsulating layer 300 is formed of a glass material, the encapsulating layer 300 has high moisture and oxygen blocking ability even when the encapsulating layer 300 is formed in a single layer, thereby increasing a lifespan of the organic light-emitting display apparatus 10.

The encapsulating layer 500 included in the organic light-emitting display apparatus 10 may be formed using the deposition apparatus 100B described above with reference to FIG. 5. In this case, since the sputter unit 200 of FIG. 5 is located outside the chamber 110 of FIG. 5, the pair of targets 210 of FIG. 5 is also located outside the chamber 110 of FIG. 5. Thus, the sputter unit 200 of FIG. 5 is easily attached to and detached from the chamber 110, and a work time needed to replace the pair of targets 210 of FIG. 5 with other targets may thus be saved.

In a deposition apparatus according to an embodiment of the present invention, argon gas is directly injected between a pair of targets and plasma may thus be more effectively and stably formed.

Also, during sputtering, the pair of targets facing each other are independently cooled and sputtering may thus be stably continuously performed without causing arching to occur.

While the present invention has been particularly shown and described with reference to exemplary embodiments thereof, it will be understood by those of ordinary skill in the art that various changes in form and details may be made therein without departing from the spirit and scope of the present invention as defined by the following claims and equivalents thereof.

What is claimed is:

1. A deposition apparatus comprising:
a chamber;
a substrate placing unit located in the chamber and on which a substrate is to be placed; and
a sputter unit for forming a thin film on the substrate,
wherein the sputter unit comprises a first target unit and a second target unit facing the first target unit,
the first and second target units are configured to mount a pair of targets, respectively, and
the first and second target units are configured to allow argon gas to be directly injected between the pair of targets.

2. The deposition apparatus of claim 1, wherein the sputter unit further comprises:
a first side portion and a second side portion facing each other and contacting corners of the first and second target units; and
a lower surface portion extending in a direction crossing the first target unit, the second target unit, the first side portion, and the second side portion, and
the argon gas is to be injected via an inlet hole formed in at least one among the first side portion, the second side portion, and the lower surface portion.

3. The deposition apparatus of claim 2, wherein the first target unit comprises a first cooling water flow path for cooling the target mounted on the first target unit,
the second target unit comprises a second cooling water flow path for cooling the target mounted on the second target unit,
wherein the first cooling water flow path and the second cooling water flow path are separated from each other to independently circulate cooling water.

4. The deposition apparatus of claim 3, wherein a third cooling water flow path is formed in the first side portion,
a fourth cooling water flow path is formed in the second side portion, and
a fifth cooling water flow path is formed in the lower surface portion.

5. The deposition apparatus of claim 4, wherein the third to fifth cooling water flow paths are connected to one another, and the third to fifth cooling water flow paths are configured to circulate cooling water independently from the first and second cooling water flow paths.

6. The deposition apparatus of claim 4, wherein one of the third to fifth cooling water flow paths is connected to one of the first and second cooling water flow paths, and the other two cooling water flow paths among the third to fifth cooling water flow paths are connected to the other cooling water flow path among the first and second cooling water flow paths.

7. The deposition apparatus of claim 1, wherein each of the first and second target units further comprises magnetic field generators at rear sides of the target thereof,
wherein the magnetic field generators of the first target unit and the magnetic field generators of the second target unit are disposed such that magnetic poles thereof are opposite to each other.

8. The deposition apparatus of claim 1, wherein the sputter unit is located outside of the chamber.

9. The deposition apparatus of claim 2, wherein the pair of targets comprise a low-liquidus temperature material.

10. The deposition apparatus of claim 9, wherein the low-liquidus temperature material comprises at least one selected from the group consisting of tin fluorophosphate glass, chalcogenide glass, tellurite glass, borate glass, and phosphate glass.

11. A deposition apparatus comprising:
a chamber;
a substrate placing unit located in the chamber and on which a substrate is to be placed; and
a sputter unit for forming a thin film on the substrate,
wherein the sputter unit has a rectangular parallelepiped shape, the upper end of which is open, and comprises a first target unit and a second target unit facing the first target unit,
the first and second target units are configured to mount a pair of targets, respectively, and
the first and second target units are configured to allow argon gas to be directly injected between the pair of targets.

12. The deposition apparatus of claim 11, wherein the low-liquidus temperature material comprises at least one selected from the group consisting of tin fluorophosphate glass, chalcogenide glass, tellurite glass, borate glass, and phosphate glass.

13. The deposition apparatus of claim 11, wherein the sputter unit further comprises:
a first side portion and a second side portion facing each other, and contacting corners of the first and second target units; and
a lower surface portion extending along a direction crossing the first target unit, the second target unit, the first side portion, and the second side portion, and
the argon gas is injected via an inlet hole formed in at least one among the first side portion, the second side portion, and the lower surface portion.

14. The deposition apparatus of claim 13, wherein the first target unit comprises a first cooling water flow path for cooling the target mounted on the first target unit,
the second target unit comprises a second cooling water flow path for cooling the target mounted on the second target unit,
wherein the first cooling water flow path and the second cooling water flow path are separated from each other to independently circulate cooling water.

15. The deposition apparatus of claim 14, wherein a third cooling water flow path is formed in the first side portion,
a fourth cooling water flow path is formed in the second side portion, and
a fifth cooling water flow path is formed in the lower surface portion.

16. The deposition apparatus of claim 15, wherein the third to fifth cooling water flow paths are connected to one another, and the third to fifth cooling water flow paths are configured to circulate cooling water independently from the first and second cooling water flow paths.

17. The deposition apparatus of claim 15, wherein one of the third to fifth cooling water flow paths is connected to one of the first and second cooling water flow paths, and the other two cooling water flow paths among the third to fifth cooling water flow paths are connected to the other cooling water flow path among the first and second cooling water flow paths.

18. The deposition apparatus of claim 11, wherein the sputter unit is located outside the chamber.

19. A method of manufacturing an organic light-emitting display apparatus, the method comprising:
forming a display unit on a substrate;
placing the substrate in a chamber; and
forming an encapsulating film to seal the display unit,
wherein the forming of the encapsulating film is performed by sputtering using a pair of targets facing each other,
wherein the pair of targets comprise a low-liquidus temperature material, and during the sputtering, argon gas is directly injected between the pair of targets.

20. The method of claim 19, wherein the sputtering is performed by a sputter unit,
wherein the sputter unit comprises:
a first target unit and a second target unit on which the pair of targets are respectively mounted to face each other;
a first side portion and a second side portion facing each other and contacting corners of the first and second target units; and
a lower surface portion extending along a direction crossing the first target unit, the second target unit, the first side portion, and the second side portion, and
the argon gas is directly injected between the pair of targets via an inlet hole formed in at least one among the first side portion, the second side portion, and the lower surface portion.

21. The method of claim 20, wherein during the sputtering, the pair of targets are independently cooled.

22. The method of claim 19, wherein the pair of targets are located outside the chamber.
